(19) United States
(12) Patent Application Publication
(10) Pub. No.: US 2010/0260940 A1
(43) Pub. Date: Oct. 14, 2010

(54) System and method for depositing metallic coatings on substrates using removable masking materials

(76) Inventor: James Charles McCown, Erda, UT (US)

Correspondence Address: MORRISS OBRYANT COMPAGNI, P.C., 734 EAST 200 SOUTH, SALT LAKE CITY, UT, 84102, US

(21) Appl. No.: 12/384,791

(22) Filed: Apr. 8, 2009

(51) Int. Cl. C23C 4/08; C23C 16/54

(52) U.S. Cl. 427/455; 118/721

(57) ABSTRACT

A system and method for depositing metallic coatings on substrates using a laser printer toner mask. A novel laser printer toner mask provides well-defined masked regions on the substrate and complementary unmasked regions. Metallic vapor from a source may be directed to a substrate with the novel mask adhered to a surface of the substrate where it condenses on the masked surface of the substrate. The mask may then be removed using any suitable technique including simply brushing the material off. Once the mask has been removed, a well-defined metallic coating remains on the unmasked regions of the substrate surface. The system and method may be used on flexible substrates such as those formed of plastic or polyester films.

### BACKGROUND OF THE INVENTION

1. Field of the Invention

This invention relates generally to methods of applying metallic coatings to surfaces. More particularly, the invention relates to a system and method for depositing metallic coatings on substrates using removable, non-photoresist masking materials.

2. Description of Related Art

Processes for depositing thin films of various materials on substrates are well known and useful. The processes can be broadly classified into two categories: physical vapor deposition (PVD) and chemical vapor deposition (CVD). As used herein, CVD refers to a plurality of reactive components that are introduced into a coating chamber. The components are caused to chemically react with one another, and the products of the reaction form the film that is coated upon the substrate. CVD processes can be conducted at various pressures and temperatures.

As used herein, PVD refers to that coating art wherein at least one of the coating components is initially placed into the coating chamber in a non-gaseous form, i.e., liquid or solid. The non-gaseous coating component is generally called the “source.” Sufficient energy is applied to the source material to change it to its vapor state, which vapor subsequently comes to rest as it condensates in film form on the substrate, perhaps after combining with other components.

There are a number of different PVD techniques, which are distinguished in the manner in which the source material is vaporized. One PVD technique involves heating the source material in a crucible. The crucible is heated until the contained source material melts and then vaporizes. A related technique involves passing electric current directly through the source material so that the source melts and then vaporizes due to Joule heating. In the latter process, the electrical energy is physically conducted to the source through a metallic conductor, and an arc is not generally created.

Another PVD technique includes ionic bombardment and sputtering deposition techniques. With these techniques, the source material is disposed within the coating chamber as a target and is bombarded with accelerated ions. The bombarding ions impart sufficient energy to the source target material to vaporize it.

Still another type of PVD technique is electric arc vapor deposition. Here, as opposed to the induction Joule heating process described above, an arc is intentionally struck, and the electrical energy contained in the arc is controlled, to vaporize the source material, thus creating a coating plasma. The source material is biased at one electric potential within the coating chamber and acts as one electrode (usually the “cathode”) of the electric arc discharge circuit. Another portion of the deposition chamber is biased at a second potential, different from the source potential, and acts as the second electrode (usually the “anode”) of the electric arc discharge circuit. An arc-initiating trigger element is positioned proximate to the cathode source and is positively biased with respect to the cathode. The trigger element is momentarily allowed to engage the surface of the cathode material, establishing a current flow path through the trigger and cathode. As the trigger element is removed from engagement with the cathode source, an electrical arc is struck, which is thereafter maintained between the cathode and the anode electrodes of the chamber. In practice, a plurality of such arcs are typically formed between the two electrodes in an operative electric arc vapor deposition chamber. This electric arc vapor deposition phenomenon is well known, and need not be discussed in detail herein. The electric arc energy is sufficient to vaporize the source material, forming a coating plasma for subsequent deposition onto substrates within the deposition chamber.

Thermal ink jetting of conductive polymers has been used for microelectronic patterning applications. However, ink jetted conductive polymers have resistivities that are approximately six orders of magnitude higher than bulk metals. This higher resistivity may be a significant disadvantage for some applications.

Still another PVD technique is known as a thermal spray process. The materials to be deposited according to the thermal spray process are melted and sprayed onto the deposition surface in droplet form. The deposition material may be supplied in either a powder-form or wire-form, and is fed into a heated region to be melted. As the materials melt, a gas stream directs the materials at the deposition surface at some velocity. The gas can also serve to aid in the formation of the droplets. These droplets then form a diverging jet of molten material that can be used to coat a large area of a particular substrate by condensation of the molten material droplets. One limitation of the thermal spray process is the inability to produce fine features by direct spraying.

A precision spray process for direct writing of deposition materials without a mask has been proposed in U.S. Pat. No. 7,294,366 and U.S. Patent Application Publication No. 2004/0197493, both to Renn et al. The Renn et al. process deposits liquid molecular precursors or precursors with particle inclusions. However, the Renn et al. process requires a subsequent processing step that converts the deposited precursor to the desired final state.

Another approach to improving the conventional thermal spray process includes using various masking schemes that have been proposed to improve the resolution of features and allow for repeatability. For example, U.S. Pat. No. 6,331,680 to Klassen et al. discloses a spray mask placed on top of the substrate to provide sharp edges on the deposited features. While such spray masks may be made of materials and surface finishes that resist adherence to the spray materials, there are occasionally problems with the mask becoming welded to the substrate after spraying, the mask lifting off portions of the unmasked regions and clean-up of the mask itself for repeated use.

Thus, it would be highly advantageous to provide a method for depositing metallic coatings on substrates that avoids at least some of the problems associated with conventional thermal spray masks. It would also be advantageous to have a process that allows the formation of well-defined electronic circuit features using thermal spray and masking techniques. It would be further advantageous to have a mask that could be adhered directly to substrates, even flexible substrates, and then easily removed or discarded.

### SUMMARY OF THE INVENTION

An embodiment of a system for depositing a patterned metallic coating on a substrate is disclosed. The system may include a mask printer for printing a non-photoresist mask on a surface of the substrate, the mask covering a masked region on the surface, the mask not covering areas where the metallic coating is desired. The system may further include a metallic vapor source for generating a metallic vapor and for selectively directing the metallic vapor to the masked surface of the substrate and thereby forming a metal layer over the mask.

An embodiment of a method for arc spraying a predetermined metal pattern on a substrate is disclosed. The method may include providing an arc spray system. The method may further include providing a metal source. The method may further include providing a screen printer having a preselected mask pattern. The method may further include providing a water-based, peelable, non-photoresist mask material. The method may further include providing a substrate. The method may further include screen printing a mask in accordance with the preselected mask pattern on a surface of the substrate using the screen printer, the mask comprising the mask material, the mask surrounding a predetermined pattern on the surface, to obtain a masked substrate. The method may further include arc spraying the metal source onto the masked substrate. The method may further include removing the mask from the substrate thereby leaving a predetermined metal pattern on the surface of the substrate.

An embodiment of a method of arc spraying a preselected metal pattern onto a substrate is disclosed. The method may include providing an arc spray system. The method may further include providing a metal for the arc spray system. The method may further include providing a substrate. The method may further include laser printing a toner mask on a surface of the substrate to obtain a masked substrate, the toner mask surrounding a preselected pattern on the surface. The method may further include arc spraying the metal onto the masked substrate. The method may further include brushing the toner mask from the substrate thereby leaving a preselected metal pattern on the surface of the substrate.

An embodiment of a method of forming a predetermined metal pattern on a flexible substrate is disclosed. The method may include printing a non-photoresist mask onto the flexible substrate to obtain a masked substrate, wherein the non-photoresist mask includes one or more openings to a surface of the flexible substrate corresponding to the predetermined metal pattern. The method may further include coating the masked substrate with a metal layer to obtain a metal-coated masked substrate. The method may further include removing the non-photoresist mask from the metal-coated masked substrate leaving the predetermined metal pattern on the flexible substrate.

Additional features and advantages of the invention will be set forth in the description which follows, and in part will be apparent from the description, or may be learned by the practice of the present invention.

### BRIEF DESCRIPTION OF THE DRAWINGS

The following drawings illustrate exemplary embodiments for carrying out the invention. Like reference numerals refer to like parts in different views or embodiments of the present invention in the drawings.

FIG. 1 illustrates a flow diagram of a general embodiment of a method and system for depositing a patterned metallic coating on a substrate according to the present invention.

FIG. 2 is an image illustrating placement of a flexible substrate onto the base of a screen printer according to method and system embodiments of the present invention.

FIGS. 3-4 are images illustrating screen printing of a non-photoresist mask onto the flexible substrate according to method and system embodiments of the present invention.

FIG. 5 is an image illustrating removal of the flexible substrate from a screen printer after the water-based peelable mask material has been applied to a flexible substrate to form an uncured non-photoresist mask according to method and system embodiments of the present invention.

FIG. 6 illustrates an image of a curing apparatus used to cure or dry an uncured non-photoresist mask, according to method and system embodiments of the present invention.

FIG. 7 is an image illustrating an electric arc vapor deposition of a metal onto a cured non-photoresist mask, according to method and system embodiments of the present invention.

FIG. 8 is an image illustrating removal of the cured non-photoresist mask using spray washing, according to method and system embodiments of the present invention.

FIG. 9 is an image of an exemplary completed flexible substrate with patterned metallic coating after removal from spray washing, according to method and system embodiments of the present invention.

FIG. 10 is a flowchart of an embodiment of a method for arc spraying a predetermined metal pattern on a substrate, according to the present invention.

FIG. 11 is a flowchart of an embodiment of a method of arc spraying a preselected metal pattern onto a substrate, according to the present invention.

FIG. 12 is a flowchart of an embodiment of a method of forming a predetermined metal pattern on a flexible substrate, according to the present invention.

### DETAILED DESCRIPTION OF THE INVENTION

The invention is a system and method for depositing a metallic coating on a substrate. The system and method are useful for any application where it is desirable to put a selective metallic coating on virtually any kind of substrate. For example, and not by way of limitation, the system and method of the present invention may be used with thin flexible substrates such as polyester films, such as those offered by E.I. Du Pont de Nemours and Company Corporation, Wilmington Del., under the trademark MYLAR.

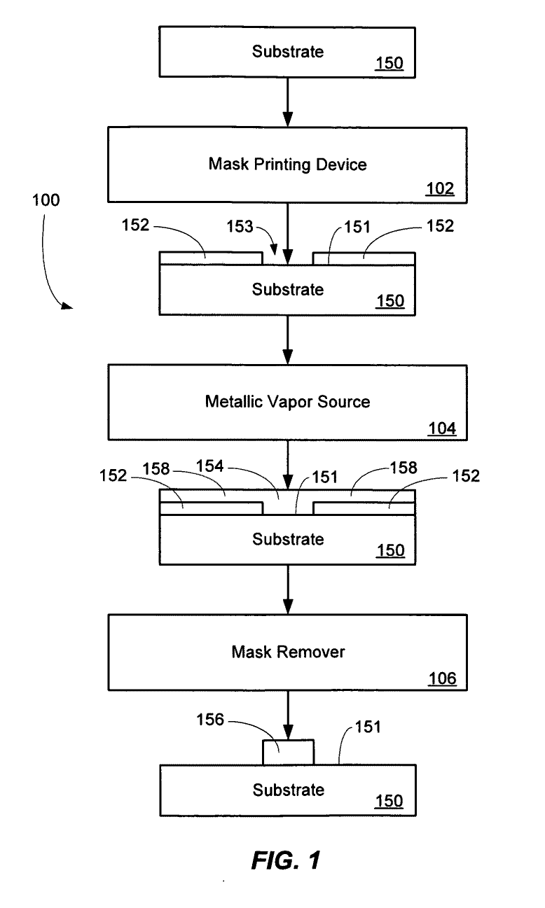

FIG. 1 illustrates a flow diagram of a general embodiment of a system 100 and method for depositing a patterned metallic coating 156 on a substrate 150 according to the present invention. System 100 may include a mask printer 102 for printing a non-photoresist mask 152 on a surface 151 of the substrate 150. The mask 152 is configured for covering a masked region on the surface 151 of the substrate 150. The mask 152 is further configured with one or more windows or openings, shown generally at arrow 153, where the metallic coating 156 is desired. System 100 may further include a metallic vapor source 104 for generating a metallic vapor and selectively directing the metallic vapor to the masked surface of the substrate and thereby forming a metal layer 154 over the mask 152. The system 100 may further include a mask remover 106 for removing the mask 152 and overlaid metal 158 from the masked region on the surface 151 of the substrate 150 thereby leaving the patterned metallic coating 156 on the substrate 150. The overlaid metal 158 is the portion of the metal layer 154 applied directly over the mask 152 and not directly to the surface 151 of the substrate 150. The metal layer 154 adheres to the unmasked substrate 150 and to the mask 152.

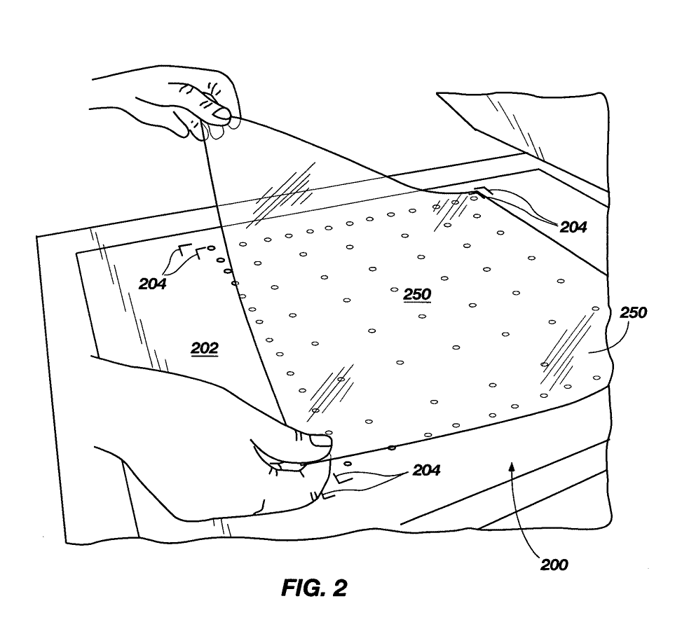

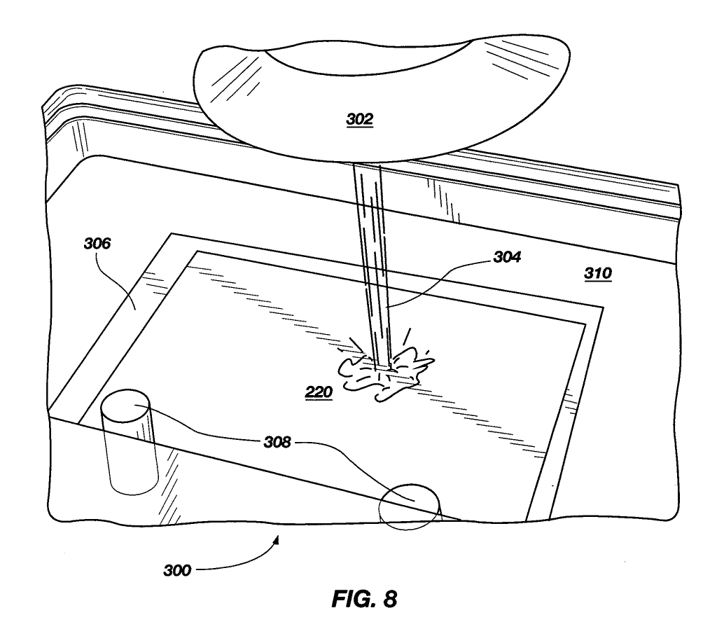

Referring again to FIG. 1, according to one embodiment of system 100, the non-photoresist mask 152 may include a screen-printed water-based peelable material. According to other embodiments of the non-photoresist mask 152, the water-based peelable material may include at least one of: water, glycol ethers, amine, pigments and resin mixtures. Various screen-printed water-based peelable materials suitable for the non-photoresist mask 152 of the present invention are available from Nazdar, 8501 Hedge Lane Terrace, Shawnee, Kans. 66227. A presently preferred non-photoresist mask 152 material is a water-based peelable mask from Nazdar identified by product number 303440WB. Because the 303440WB product is water-based material, it is particularly suited for removal by the high pressure spray wash 300 (see FIG. 8 and related discussion below). According to yet another embodiment of system 100, the mask printer 102 may include a screen printer 200 and squeegee 210 (see FIGS. 2-5 and related discussion below). The screen printer 200 and squeegee 210 are particularly well suited for use with the Nazdar 303440WB mask 152 material.

According to still another embodiment of system 100, the non-photoresist mask 152 includes laser printer toner material. According to a particular embodiment of system 100, the mask printer 102 may be a laser printer for depositing laser printer toner material on the substrate 150 in the desired mask pattern. According to one embodiment of system 100, the metallic vapor may be formed of one of the following metals: zinc, tin, aluminum and copper. According to another embodiment of system 100, the metallic vapor may be formed of one of the following metals: zinc, tin, aluminum, copper, gold, silver, platinum and palladium. According to various embodiments of system 100, the metallic vapor source may be from any one of the following: arc spraying, physical vapor deposition and chemical vapor deposition.

FIGS. 2-9 are a sequence of photographs of a presently preferred embodiment of a system and method for depositing a metallic coating on a flexible substrate according to the present invention. More particularly, FIGS. 2-9 illustrate the basic components of an exemplary system for depositing a metallic coating on a flexible substrate including a mask printing device 102 (FIG. 1), a metallic vapor source 104 (FIG. 1) and a mask remover 106 (FIG. 1). FIGS. 2-9 also illustrate exemplary method steps performed in order to deposit a metallic coating on a flexible substrate according to the present invention.

More particularly, FIG. 2 is an image illustrating placement of a flexible substrate 250, namely a sheet of polyester film, onto the base 202 of a screen printer 200 (only a portion shown in FIG. 2). The flexible substrate 250 may be held in place on the base 202 using tape, adhesive, vacuum backing or any other means known to those of ordinary skill in the screen printing arts. Consistent placement of the flexible substrate 250 on the base 202 for manufacturing in quantity may be achieved using corner marks 204 or any other suitable means for registering the placement of the flexible substrate 250 onto the base 202 of the screen printer.

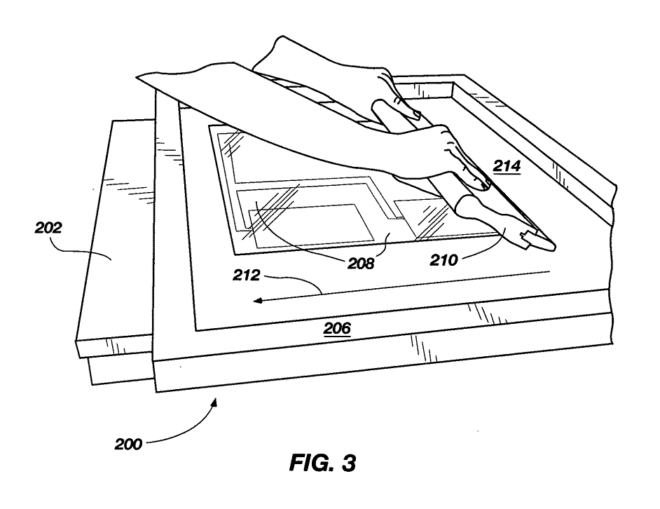

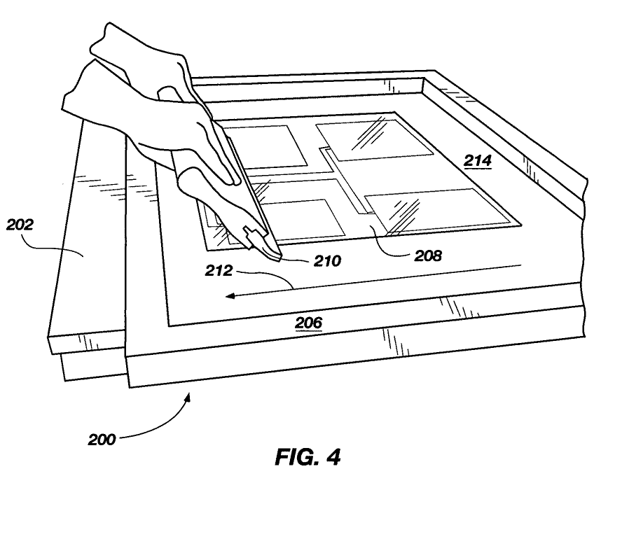

FIGS. 3-4 illustrate screen printing according to exemplary method and system embodiments of the present invention. More particularly, FIG. 3 is an image illustrating a screen printer 200 and screen printing of a non-photoresist mask onto the flexible substrate 250 (FIG. 2). A water-based peelable mask material, such as Nazdar 303440WB placed on the screen printer, e.g., near the top 214 of screen printer frame 206, and then forced through openings, shown generally at arrows 208 pointing to white spaces, in the screen printer frame 206 by dragging a squeegee 210 across the screen printer frame 206 in the direction shown at arrow 212.

FIG. 3 illustrates the initial position of the squeegee 210 prior to dragging it across the screen printer frame 206, while FIG. 4 illustrates the final position of the squeegee 210 after it has been dragged across the screen printer frame 206 and forced the water-based peelable mask material onto the surface of the flexible substrate 250 (FIG. 2). The screen printing techniques illustrated in FIGS. 3-4 are well known to those skilled in the art of screen printing and thus, will not be further elaborated herein.

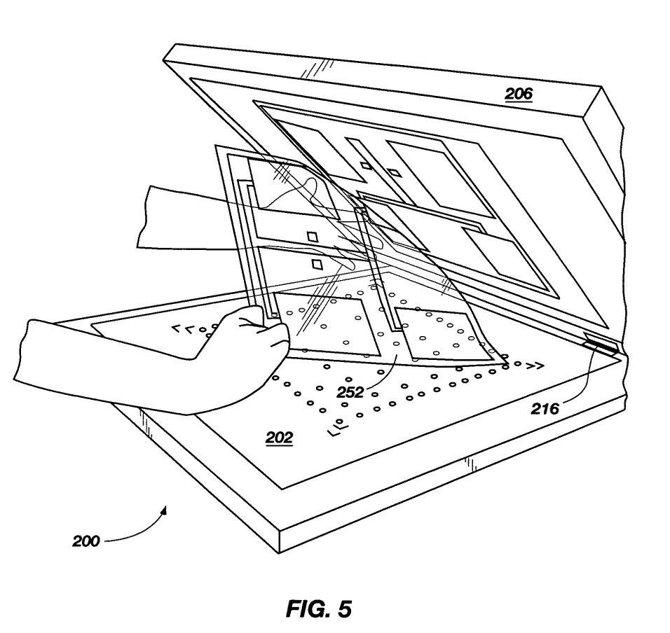

FIG. 5 is an image illustrating removal of an uncured non-photoresist mask 252 from the screen printer 200 after the water-based peelable mask material has been applied to the flexible substrate 250 (FIG. 2), according to method and system embodiments of the present invention. FIG. 5 also shows the base 202 and screen printer frame 206 of the screen printer 200. The screen printer frame 206 may be hinged 216 to the base 202. Screen printer 200 is a specific embodiment of the more general mask printer 102 (FIG. 1).

At this stage of the process, the uncured non-photoresist mask 252 may require curing or drying before further use. According to one embodiment of the invention, the uncured non-photoresist mask 252 may be cured or dried in ambient air. According to another embodiment, the uncured non-photoresist mask 252 may be cured or dried at an elevated temperature, e.g., in an oven. According to yet another embodiment, the uncured non-photoresist mask 252 may be cured or dried using forced ambient temperature air.

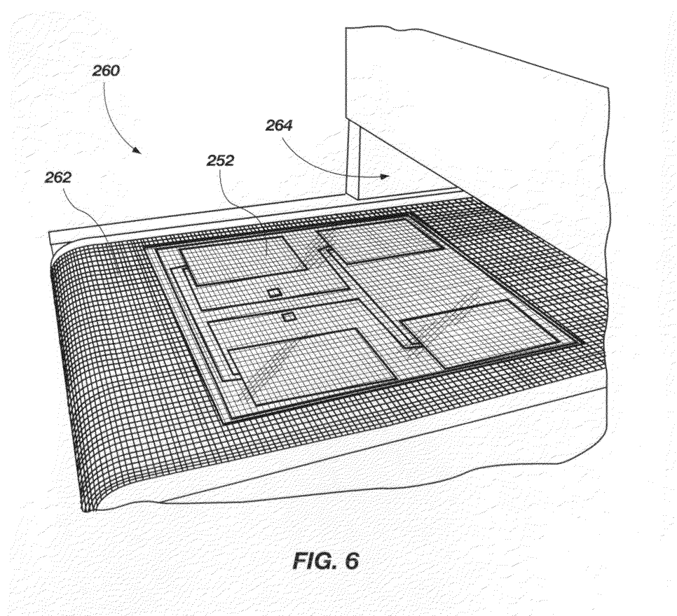

FIG. 6 illustrates a curing apparatus 260 used to cure or dry an uncured non-photoresist mask 252. Curing apparatus 260 may include a conveyor belt 262 for transporting the uncured non-photoresist mask 252 through a chamber 264 having forced air. According to still another embodiment, the uncured non-photoresist mask 252 may be cured or dried using forced air and at an elevated temperature (i.e., higher than ambient temperature). The use of a curing apparatus 260 is optional, and is, of course, dependent on the particular material selected for the non-photoresist mask 152 (FIG. 1). Where curing of the uncured non-photoresist mask 252 is desired, it will be understood that various methods of curing or drying the uncured non-photoresist mask 252 will be readily apparent to one of skill in the art and thus, will not be further elaborated herein.

The next step in the process may include forming a metallic layer over the cured non-photoresist mask 252. It will be understood that there are a number of known methods for applying a metallic coating to a substrate, e.g., chemical vapor deposition and physical vapor deposition, and all of their variations as discussed herein which may be suitable for applying a metallic coating over a cured non-photoresist mask 252, according to the present invention. This disclosure includes a description of one particular physical vapor deposition process, electric arc vapor deposition in the background section. Electric arc vapor deposition (also referred to as “arc spraying”) may employ any one of a number of source metals as a suitable metallic vapor source, for example and not by way of limitation, zinc, tin, aluminum, copper, gold, silver, platinum and palladium. These metals may come in the form of a power, pellets, rods or any other bulk shape suitable for the particular arc vapor deposition system employed. As relatively significant quantities of the metal may be applied to the cured non-photoresist mask 252, the choice of one metal over another may be governed by cost economics rather than relative metallic properties of specific metals.

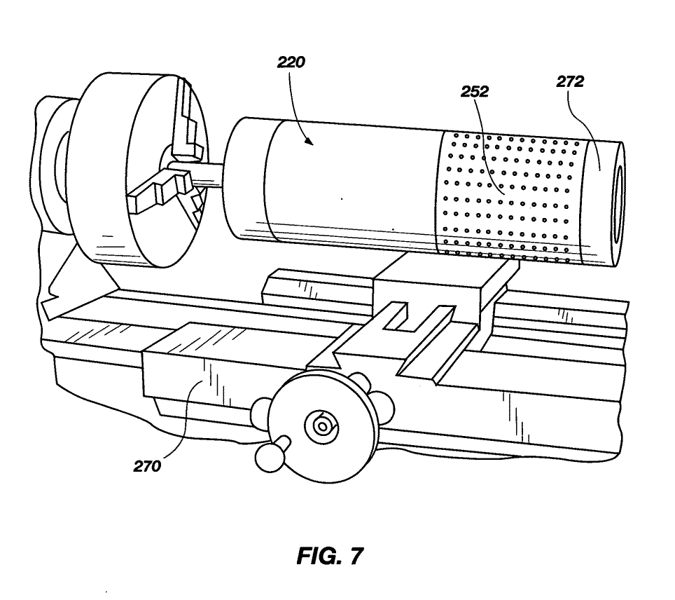

FIG. 7 is an image illustrating a particular embodiment of electric arc vapor deposition of a metal onto the cured non-photoresist mask 252, according to the present invention. Relative to integrated circuit processing, the application of a metal layer to the cured non-photoresist mask 252, which may have a significantly larger surface area, introduces the problem of applying a relatively even layer of metal to the entire surface area of the cured non-photoresist mask 252. The embodiment illustrated in FIG. 7 solves this problem by wrapping the cured non-photoresist mask 252 around a drum 272 attached to a lathe 270. The cured non-photoresist mask 252 may be attached to drum 272 using tape, vacuum, adhesive, clips or any other suitable means for attaching a flexible sheet to a cylindrical surface.

An electric arc vapor deposition system (hidden behind the drum 272) provides a relatively concentrated metallic vapor source which may then be sprayed by pressurized air onto the surface of the cured non-photoresist mask 252 which is rotating on the drum 272 under control of the lathe 270. In this way, the metallic vapor is spread evenly over the surface of the cured non-photoresist mask 252 to form a metal coated substrate, shown generally at arrow 220. Exemplary arc vapor deposition systems for use according to the principles of the present invention include Models 8830 and 8835 Arc Spray Systems available from Praxair Surface Technologies TAFA Incorporated, 146 Pembroke Road, Concord, N.H. 03301-5706. However, it will be understood that any suitable physical vapor deposition system with any suitable metal source (powder, pellets, rods, etc.) may be used consistent with the principles of the present invention.

At this stage in the process, referring again to FIG. 1, it is desirable to remove the non-photoresist mask 152 and any overlaid metallic coating in order to leave a metal layer 154 on areas where metallic coating is desired 153. It is desirable to be able to remove the mask 152 without removing the desired patterned metallic coating 156. According to one embodiment of system 100, the mask remover 106 may include mechanical brushing (not shown in FIG. 1) of the substrate 150 to remove the mask 152 and the overlaid metal from the masked region. Mechanical brushing may be performed by hand or by machine as known to those of ordinary skill in the art. According to a particular embodiment of the present invention, mechanical brushing may include using a wire brush in a hand die grinder on the metal layer 154 to remove the mask 152 and the overlaid metal from the masked region.

It will be understood that many other suitable techniques for removing a removable mask 152 from a substrate 150 will be readily apparent to one of ordinary skill in the art. All of such other suitable techniques fall within the spirit and scope of the present invention. One such alternative technique is the use of a high pressure spray wash as a mask remover 106 for removing the mask 152 and overlaid metal 158 from the masked region on the surface 151 of the substrate 150, as further described below.

Referring now to FIG. 8, an embodiment of a high pressure spray wash system 300 is shown. High pressure spray wash system 300 may include a nozzle 302 for directing a stream of water 304, or other suitable solvent, onto the metal coated substrate 220. System 300 may further include a substrate table 306 or other generally flat surface for supporting the flexible metal coated substrate 220 during removal of the mask 152 (FIG. 1) and overlaid metal 158 (FIG. 1). The metal coated substrate 220 may be held to the surface of the substrate table 306 using weights 308, tape (not shown), adhesive (not shown), clips (not shown) or any other suitable means for adhering the flexible metal coated substrate 220 to the substrate table 306. System 300 may further include a tub 310 and drain (not shown) for gathering and disposing of the water and removed portions of the mask 152 (FIG. 1) and overlaid metal 158 (FIG. 1) during the spray washing. The high pressure spray wash system 300 illustrated in FIG. 8 is a specific example of the more general mask remover 105 (FIG. 1).

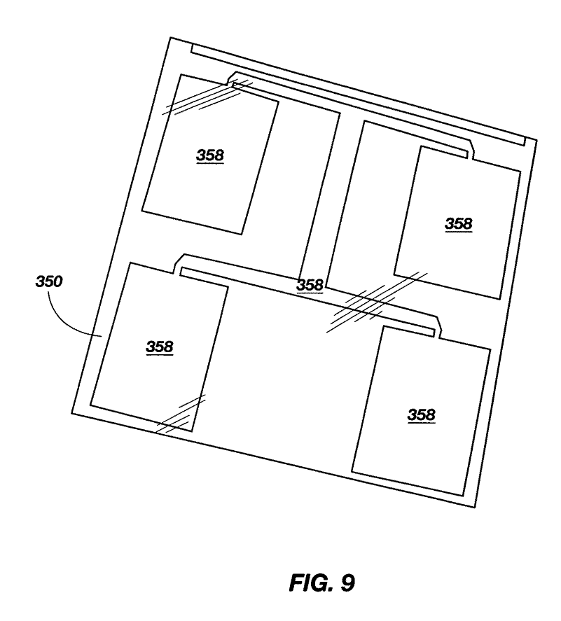

FIG. 9 is an image of an exemplary completed flexible substrate 350 with patterned metallic coating 358 after removal from spray washing according to a method of the present invention. The patterned metallic coating 358 may be, for example and not by way of limitation, an electrical circuit. The completed flexible substrate 350 may then be used in its intended application.

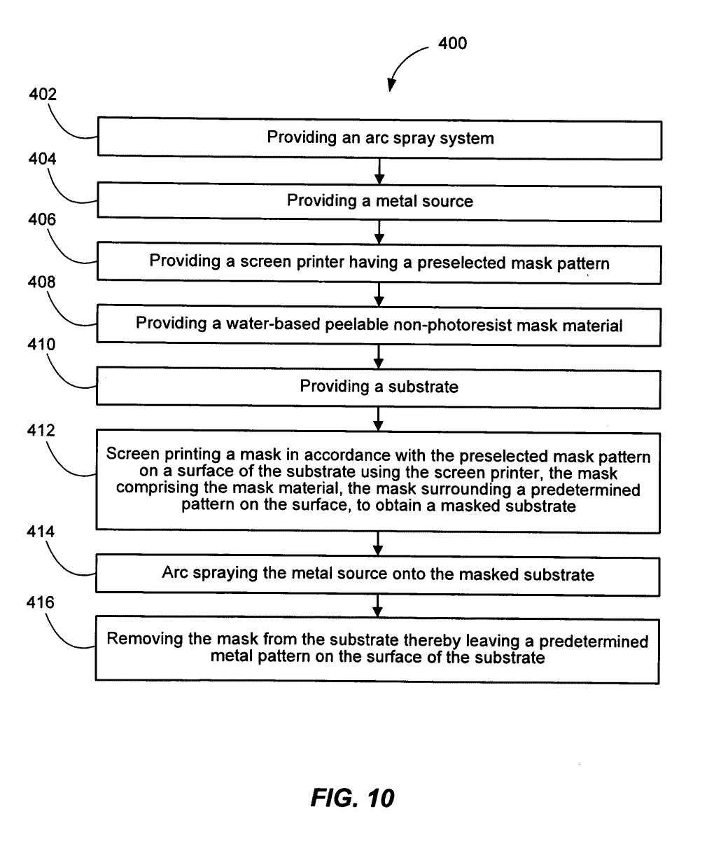

FIG. 10 is a flowchart of an embodiment of a method 400 for arc spraying a predetermined metal pattern on a substrate, according to the present invention. Method 400 may include providing an arc spray system 402. Method 400 may further include providing a metal source 404. Method 400 may further include providing a screen printer having a preselected mask pattern 406. Method 400 may further include providing a water-based peelable non-photoresist mask material 408. Method 400 may further include providing a substrate 410. Method 400 may further include screen printing a mask 412 in accordance with the preselected mask pattern on a surface of the substrate using the screen printer, the mask comprising the mask material, the mask surrounding a predetermined pattern on the surface, to obtain a masked substrate. Method 400 may further include arc spraying the metal source onto the masked substrate 414. Method 400 may further include removing the mask from the substrate 416 thereby leaving a predetermined metal pattern on the surface of the substrate.

According to another embodiment of method 400, providing the metal source may include providing at least one of: zinc, tin, aluminum and copper. According to still another embodiment of method 400, providing the metal source may include providing at least one of: zinc, tin, aluminum, copper, gold, silver, platinum and palladium.

According to yet another embodiment of method 400, providing the substrate may include providing an elastically deformable plastic substrate. According to another embodiment of method 400, providing the substrate may include providing a polyester film. Polyester films by the brand name MYLAR® available from E. I. du Pont de Nemours and Company Corporation, DE, are particularly suitable as flexible substrates for the application of patterned metal layers according to the present invention.

According to an embodiment of method 400, removing the mask from the substrate may include washing the substrate with a high-pressure water spray, see, e.g., FIG. 8 and related discussion herein. According to another embodiment of method 400, removing the mask from the substrate may include brushing the mask off of the substrate.

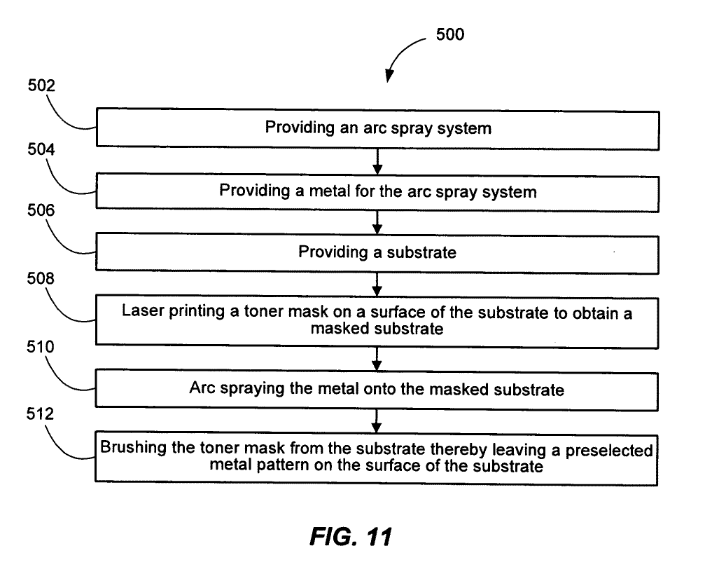

FIG. 11 is a flowchart of an embodiment of a method 500 of arc spraying a preselected metal pattern onto a substrate, according to the present invention. Method 500 may include providing an arc spray system 502. Any suitable arc vapor deposition system may be used consistent with the principles of the present invention. Method 500 may further include providing a metal 504 for the arc spray system. According to various embodiments, providing the metal 504 may include providing at least one of the following metals: zinc, tin, aluminum, copper, gold, silver, platinum and palladium. According to particular embodiments of method 500, providing a metal 504 may include providing one of the following metals: zinc, tin, aluminum and copper.

Method 500 may further include providing a substrate 506. Method 500 may be used with virtually any substrate material. According to a particular embodiment of method 500, providing a substrate may include providing a polyester film, such as the polyester film identified under the brand name MYLAR® available from E. I. du Pont de Nemours and Company Corporation.

Method 500 may further include laser printing a toner mask 508 on a surface of the substrate to obtain a masked substrate. According to one embodiment, the substrate may be a sheet of polyester film upon which the toner mask is printed directly. It will be understood that the toner mask may take any desirable shape that may be printed with a conventional laser printer. It will also be understood that a laser printer (not shown) is a specific example of the more general mask printer 102 (FIG. 1) described above. Laser printers and laser printer toner (pigment powder) are well known to those of ordinary skill in the art and, thus, will not be further elaborated herein. According to one embodiment of method 500, the toner mask may surround a preselected pattern on the surface of the substrate. For example and not by way of limitation, the preselected pattern may be an electrical circuit pattern.

Method 500 may further include arc spraying the metal 510 onto the masked substrate. According to this step of method 500, the metal vapor generated from the arc spraying system condenses as a metal layer on the masked substrate, thereby adhering to the toner mask and to any openings in the toner mask that expose the top surface of the substrate. According to a specific embodiment, arc spraying the metal 510 onto the masked substrate may be achieved using the components shown in FIG. 7, namely a lathe 270, drum 272 and arc sprayer (hidden behind drum 272).

Referring again to FIG. 11, method 500 may further include brushing the toner mask 512 from the substrate thereby leaving a preselected metal pattern on the surface of the substrate. Brushing the toner mask 512 is a specific method for removing a mask. Even more specifically, brushing the toner mask 512 may include applying a wire brush in a hand die grinder to the masked substrate thereby removing the mask and any metal adhered to the mask. Thus, a wire brush in a hand die grinder is a specific embodiment of mask remover 106 (FIG. 1). The use of a toner mask on a polyester film substrate has the favorable property of being relatively easily removed along with its corresponding overlaid metal layer 158 (FIG. 1), either by brushing 512 or alternatively, by using high pressure spray washing (see FIG. 8 and related discussion herein). Wire brushes and hand die grinders are well known in the art and, thus, their workings and configurations will not be further elaborated herein.

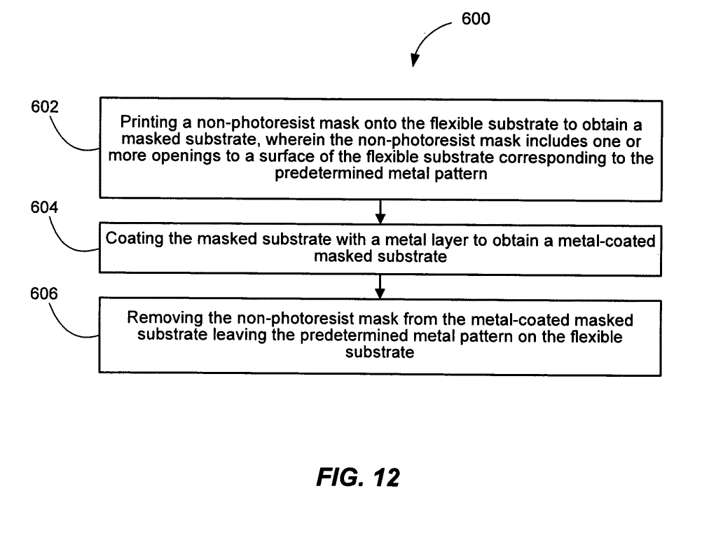

FIG. 12 is a flowchart of an embodiment of a method 600 of forming a predetermined metal pattern on a flexible substrate, according to the present invention. Method 600 may include printing a non-photoresist mask 602 onto the flexible substrate to obtain a masked substrate, wherein the non-photoresist mask includes one or more openings to a surface of the flexible substrate corresponding to the predetermined metal pattern. Method 600 may further include coating the masked substrate with a metal layer 604 to obtain a metal-coated masked substrate. Method 600 may further include removing the non-photoresist mask 606 from the metal-coated masked substrate leaving the predetermined metal pattern on the flexible substrate.

In another embodiment of method 600, printing the non-photoresist mask onto the flexible substrate may include screen printing a water-based peelable mask material onto the flexible substrate. One example of this embodiment is shown, e.g., in FIGS. 2-5 and related discussion herein. According to yet another embodiment of method 600, printing a non-photoresist mask onto the flexible substrate may include screen printing a water-based peelable mask material onto a polyester film substrate. One example of this particular embodiment is again shown, e.g., in FIGS. 2-5 and related discussion herein.

In one embodiment of method 600, coating the masked substrate with a metal layer may include arc spraying the metal layer onto the masked substrate. A particular example of this embodiment is shown, e.g., in FIG. 7 and related discussion herein. According to another embodiment of method 600, coating the masked substrate with a metal layer may include arc spraying the metal layer onto the masked substrate, wherein the masked substrate is wrapped around a rotating cylindrical surface or drum 272 (FIG. 7). One example of this particular embodiment is also shown, e.g., in FIG. 7 and related discussion herein. According to still another embodiment of method 600, removing the non-photoresist mask from the metal-coated masked substrate may include washing the substrate with a high-pressure water spray. One example of this embodiment is shown, e.g., in FIG. 8 and related discussion herein.

While the foregoing advantages of the present invention are manifested in the detailed description and illustrated embodiments of the invention, a variety of changes can be made to the configuration, design and construction of the invention to achieve those advantages. Hence, reference herein to specific details of the structure and function of the present invention is by way of example only and not by way of limitation.

What is claimed is:

1. A system for depositing a patterned metallic coating on a substrate, the system, comprising:
a mask printer for printing a non-photoresist mask on a surface of the substrate, the mask covering a masked region on the surface, the mask not covering areas where the metallic coating is desired; and
a metallic vapor source for generating a metallic vapor and for selectively directing the metallic vapor to the masked surface of the substrate and thereby forming a metal layer over the mask.

2. The system according to claim 1, further comprising a mask remover for removing the mask and overlaid metal from the masked region on the surface of the substrate, thereby leaving the patterned metallic coating on the substrate.

3. The system according to claim 2, wherein the mask remover comprises a high pressure spray wash.

4. The system according to claim 2, wherein the mask remover comprises mechanical brushing of the substrate to remove the mask and the overlaid metal from the masked region.

5. The system according to claim 1, wherein the non-photoresist mask comprises a screen-printed water-based peelable material.

6. The system according to claim 5, wherein the water-based peelable material comprises at least one of: water, glycol ethers, amine, pigments and resin mixtures.

7. The system according to claim 1, wherein the mask printer comprises a screen printer and squeegee.

8. The system according to claim 1, wherein the non-photoresist mask comprises laser printer toner material.

9. The system according to claim 1, wherein the mask printer comprises a laser printer for depositing laser printer toner material.

10. The system according to claim 1, wherein the metallic vapor comprises one of: zinc, tin, aluminum, copper, gold, silver, platinum and palladium.

11. The system according to claim 1, wherein the metallic vapor source comprises one of: arc spraying, physical vapor deposition and chemical vapor deposition.

12. A method for arc spraying a predetermined metal pattern on a substrate, the method comprising:
providing an arc spray system;
providing a metal source;
providing a screen printer having a preselected mask pattern;
providing a water-based, peelable, non-photoresist mask material;
providing a substrate;
screen printing a mask in accordance with the preselected mask pattern on a surface of the substrate using the screen printer, the mask comprising the mask material, the mask surrounding a predetermined pattern on the surface, to obtain a masked substrate;
arc spraying the metal source onto the masked substrate; and
removing the mask from the substrate thereby leaving a predetermined metal pattern on the surface of the substrate.

13. The method according to claim 12, wherein providing the metal source comprises providing at least one of: zinc, tin, aluminum and copper.

14. The method according to claim 12, wherein providing the substrate comprises providing an elastically deformable plastic substrate.

15. The method according to claim 12, wherein providing the substrate comprises providing a polyester film.

16. The method according to claim 12, wherein removing the mask from the substrate comprises washing the substrate with a high-pressure water spray.

17. A method of arc spraying a preselected metal pattern onto a substrate, the method comprising:
providing an arc spray system;
providing a metal for the arc spray system;
providing a substrate;
laser printing a toner mask on a surface of the substrate to obtain a masked substrate, the toner mask surrounding a preselected pattern on the surface;
arc spraying the metal onto the masked substrate; and
brushing the toner mask from the substrate thereby leaving a preselected metal pattern on the surface of the substrate.

18. The method according to claim 17, wherein providing the metal comprises providing at least one of: zinc, tin, aluminum and copper.

19. The method according to claim 17, wherein providing the substrate comprises providing a polyester film.

20. The method according to claim 17, wherein brushing the mask comprises applying a wire brush in a hand die grinder to the masked substrate thereby removing the mask and any metal adhered to the mask.

21. A method of forming a predetermined metal pattern on a flexible substrate, the method comprising:
printing a non-photoresist mask onto the flexible substrate to obtain a masked substrate, wherein the non-photoresist mask includes one or more openings to a surface of the flexible substrate corresponding to the predetermined metal pattern;
coating the masked substrate with a metal layer to obtain a metal-coated masked substrate; and
removing the non-photoresist mask from the metal-coated masked substrate leaving the predetermined metal pattern on the flexible substrate.

22. The method according to claim 21, wherein printing the non-photoresist mask onto the flexible substrate comprises screen printing a water-based peelable mask material onto the flexible substrate.

23. The method according to claim 21, wherein printing a non-photoresist mask onto the flexible substrate comprises screen printing a water-based peelable mask material onto a polyester film substrate.

24. The method according to claim 21, wherein coating the masked substrate with a metal layer comprises arc spraying the metal layer onto the masked substrate.

25. The method according to claim 21, wherein coating the masked substrate with a metal layer comprises arc spraying the metal layer onto the masked substrate, wherein the masked substrate is wrapped around a rotating cylindrical surface.

26. The method according to claim 21, wherein removing the non-photoresist mask from the metal-coated masked substrate comprises washing the substrate with a high-pressure water spray.
